(19) United States
(12) Patent Application Publication
(10) Pub. No.: US 2016/0230283 A1
(43) Pub. Date: Aug. 11, 2016

(54) Fused Material Deposition Microwave System And Method

(71) Applicant: ESCAPE DYNAMICS INC., Broomfield, CO (US)

(72) Inventors: Dmitriy Tseliakhovich, Broomfield, CO (US); Tak Sum Chu, San Francisco, CA (US); Gonzalo Martinez, Novato, CA (US)

(21) Appl. No.: 14/619,998

(22) Filed: Feb. 11, 2015

(51) Int. Cl. C23C 16/511; C23C 16/44; C23C 16/46; C23C 16/52; C23C 16/455

(52) U.S. Cl. CPC C23C 16/511; C23C 16/52; C23C 16/45563; C23C 16/46; C23C 16/4412; C23C 16/463

(57) ABSTRACT

A fused material deposition microwave system and method include at least one high power microwave source, at least one deposition nozzle having adjustable outlet diameter for depositing one or more materials, a waveguide for guiding microwave energy to the deposition nozzle to melt the materials, and a material source to supply one or more materials to the deposition nozzle. The system and method further include a controller for controlling the deposition nozzle, microwave energy, and material source according to a computer-aided manufacturing set of instructions to deposit and fuse molten material on a workpiece. The system and method provide improvements in additive manufacturing of three-dimensional objects that are particularly beneficial for manufacturing objects made of metals and ceramics.

### BACKGROUND

Additive manufacturing processes are used to produce three-dimensional objects. Layers of material are deposited and bonded together (optionally onto an object or a substrate) according to a prescribed pattern or design to create a 3-dimensional (3D) object. A 3D printer implements this printing process by depositing a layer of material (e.g., liquid, powder, extrusion (e.g., wire) or sheet) onto a pre-existing object or substrate and subsequently fusing, by the focused application of energy, some or all of the material to the pre-existing object or substrate according to the prescribed pattern. The process repeats to deposit and fuse multiple layers (each layer representing a cross section through the object) to form the 3D object.

Existing 3D printing processes include selective laser melting (SLM), direct metal laser sintering (DMLS), selective laser sintering (SLS), fused deposition modeling (FDM), stereo-lithography (SLA), laminated object manufacturing (LOM), electron beam melting (EBM), stereo-lithography (STL), digital light processing (DLP), and direct metal deposition (DMD). These additive manufacturing methods, however, have several drawbacks and limitations. For example, there are trade-offs between equipment and material costs, object resolution, speed, and properties of the finished object. Typically, compromises are required in order to achieve specific project objectives. These compromises are especially limiting in the case of additive manufacturing of metals and ceramics as well as large parts made of any material. For example, to address the costs associated with 3D printing of metal objects, a non-metallic object may first be created using 3D printing and then used to produce a mold for casting metal copies. Alternatively, additive manufacturing of metals may require a multi-step process in which several long and costly steps are required, limiting the benefits of additive manufacturing.

Laser-based processes for additive manufacturing of metals are described for example in U.S. Pat. No. 6,122,564 and U.S. Pat. No. 7,765,022. In these processes, a laser beam is focused onto an object, creating a melt pool into which additional powdered metal is injected. However, laser-based 3D printing processes for metallic and ceramic parts are often slow and limited in the size of objects they can print. Although resolution of such laser devices is high, the speed of generating the object is often slow because the laser beam is narrowly focused and has a small diameter requiring rapid movement (scanning) across each deposited layer (resulting in non-uniform heat distribution, poor fusing, and inconsistent mechanical properties between different parts). Moreover, penetration of the laser beam into certain materials is limited, resulting in the thickness of each added layer being small. Further, small diameter and small penetration thickness of a laser beam often can cause significant residual stress in the material leading to undesirable properties of the work piece.

Selective laser sintering methods, where a laser beam fuses layers of metal inside of powder bed, such as described in U.S. Pat. No. 4,863,538, are limited in the size of parts that can be produced because the parts are fabricated inside a large volume of metallic powder deposited layer by layer in the printing process, and hence the manufacturing process requires a very large amount of high quality uniform powder material. For large scale objects, the amount of power required for manufacturing becomes impractical.

Other methods of applying heat during the sintering portions of additive manufacturing processes entail a number of drawbacks and limitations. For example, sintering beams derived from frequencies around 2.45 GHz (i.e., wavelengths approximately equal to 12.22 cm) may be used; but the energy distribution of such beams can be difficult to control, with the beam being excessively diffused and unfocussed. As a result, heat is unintentionally applied outside of intended target areas, and precise control over depths of energy penetration become impossible.

### SUMMARY OF THE INVENTION

A fused material deposition microwave system includes a high power microwave source, at least one deposition nozzle having adjustable outlet diameter for depositing one or more materials, a waveguide for guiding microwave energy to the deposition nozzle to melt the materials, and a material source to supply one or more materials to the deposition nozzle. The system further includes a controller for controlling the deposition nozzle, microwave energy flow, and material source, according to a computer-aided manufacturing (CAM) set of instructions to deposit and fuse molten material on a workpiece.

A fused material deposition microwave method includes delivering one or more materials to a deposition nozzle, guiding microwave energy from a high power microwave source to the deposition nozzle to melt the one or more materials, and controlling the material delivery, microwave energy, and position of the deposition nozzle according to a computer-aided manufacturing (CAM) set of instructions, thereby depositing and fusing molten material into a workpiece.

### BRIEF DESCRIPTION OF THE FIGURES

FIG. 1 shows a fused material deposition microwave system, in an embodiment.

FIG. 2 shows a cross-sectional view of a fused material deposition microwave system with a flexible waveguide, in an embodiment.

FIG. 3 shows a cross-sectional view of a fused material deposition microwave system with a reflector, in an embodiment.

FIG. 4 shows a cross-sectional view of a fused material deposition microwave system with a waveguide including one or more reflectors, in an embodiment.

FIG. 5 shows a cross-sectional view of a portion of a fused material deposition microwave system highlighting a deposition nozzle, in an embodiment.

FIG. 6 shows a cross-sectional view of a deposition nozzle with adjustable waveguide position, in an embodiment.

FIG. 7 shows a cross-sectional view of a deposition nozzle with a separate waveguide and material conduit, in an embodiment.

FIG. 8 shows a portion of a fused material deposition microwave system, highlighting a waveguide enclosed in a conduit with four channels for deposition of different materials, in an embodiment.

FIG. 9 shows a cross-sectional view of a fused material deposition microwave system with a robotic arm, in an embodiment.

FIG. 10 shows a cross-sectional view of a mobile fused material deposition microwave system, in an embodiment.

FIG. 11 is a block diagram of a controller for a fused material deposition microwave system, in an embodiment.

FIG. 12 is a flowchart illustrating one exemplary method for microwave control during fused material deposition, in an embodiment.

### DETAILED DESCRIPTION OF THE EMBODIMENTS

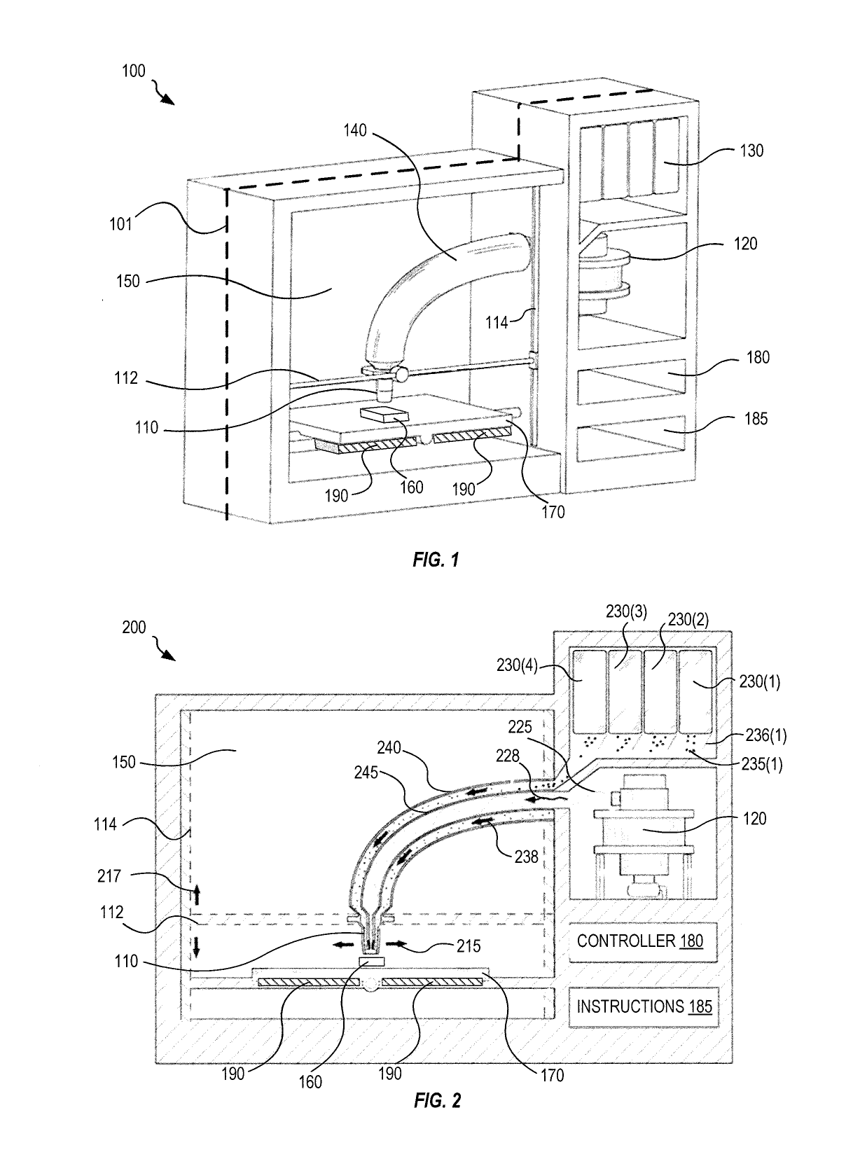

FIG. 1 shows one fused material deposition microwave system 100. System 100 includes a deposition nozzle 110 for depositing one or more materials, a microwave energy source 120 for providing microwave energy, and a material source 130 for supplying one or more materials. Examples of microwave energy source 120 include a gyrotron, klystron, magnetron, or other source of high-power microwave energy. Microwave energy source 120 is for example an integrated high-power microwave source that includes a compact power supply. Alternatively, microwave energy source 120 is modular, has an external power supply, and is coupled to a larger manufacturing apparatus. The modular embodiment is beneficial when system 100 is for example integrated into a CNC mill or a laser-based 3D printer. In an embodiment, the output power of microwave energy source 120 is adjusted by tuning current and voltage of an internal electron gun that directly affects electron current flowing inside a microwave cavity (e.g., inside a gyrotron). The change in electron current directly affects the amount of microwave energy created in the gyrotron and released.

Returning to FIG. 1, a conduit 140 guides material from material source 130 to deposition nozzle 110. Material source 130 includes for example a source of pressurized gas or fluid configured to carry material from the material source 130 via a conduit 140 to the deposition nozzle 110. Conduit 140 is flexible and moveable in three dimensions and includes a flexible waveguide that guides a beam of microwave energy from microwave energy source 120 to deposition nozzle 110. Inside deposition nozzle 110, material and microwave energy interact causing the material to melt immediately before or immediately after leaving the nozzle. Deposition nozzle 110 deposits molten material, which fuses to form a desired workpiece 160. System 100 includes a deposition chamber 150, to provide a controlled atmosphere for example. In an embodiment, deposition chamber 150 controls temperature, pressure, and gas composition. Gas composition includes for example a non-oxidative gas such as hydrogen or argon used to prevent oxidation of workpiece 160. In an embodiment, air is removed from nearby the workpiece by displacing it with an inert gas, thereby creating a substantially oxygen-free atmosphere in chamber 150. Workpiece 160 is formed on a moveable base, such as moveable base 170. System 100 may include a cooler 190 used to cool moveable base 170, thereby increasing the rate at which molten material solidifies. Cooler 190 may include one or more of the following components: a solid state heat pump, refrigerator, air heat exchanger with a fan, or a coolant loop with a pump that drives flow of a cooling liquid. A cooler 190 may be positioned at or inside a moveable base 170 or it may be positioned elsewhere within the deposition chamber 150. Cooling takes place while material is deposited, providing an advantage in efficiency over existing additive manufacturing systems and methods that heat and cool material in cycles.

Again returning to FIG. 1, deposition nozzle 110 moves to a desired location along a first rail 112 and a second rail 114 to accommodate motion of nozzle 110. In an embodiment, actuators rotate the nozzle around one or more of the rails to allow rotational degrees of freedom. Thus, system 100 deposits molten material in the desired location by coordinating the position of moveable base 170 and deposition nozzle 110. Motion of base 170 along with motion of deposition nozzle 110 provides higher flexibility of a fabrication process and enables fabrication of more complex parts. Deposited molten material solidifies into the desired shape of workpiece 160, which is optionally aided by atmospheric control of deposition chamber 150 and cooling of moveable base 170 by cooler 190. Cooling is for example further provided to workpiece 160 by distributing a gas or liquid through conduit 140 and out deposition nozzle 110. In an embodiment, cooling of deposition nozzle 110 is accomplished by immersion in a liquid. Deposition chamber 150 is for example partially filled with liquid configured to conduct away heat produced during material deposition. A controller 180 is provided to control all controllable features of system 100, including deposition nozzle 110, microwave energy source 120, material source 130, deposition chamber 150, moveable base 170, and cooler 190 according to a computer-aided manufacturing (CAM) set of instructions 185.

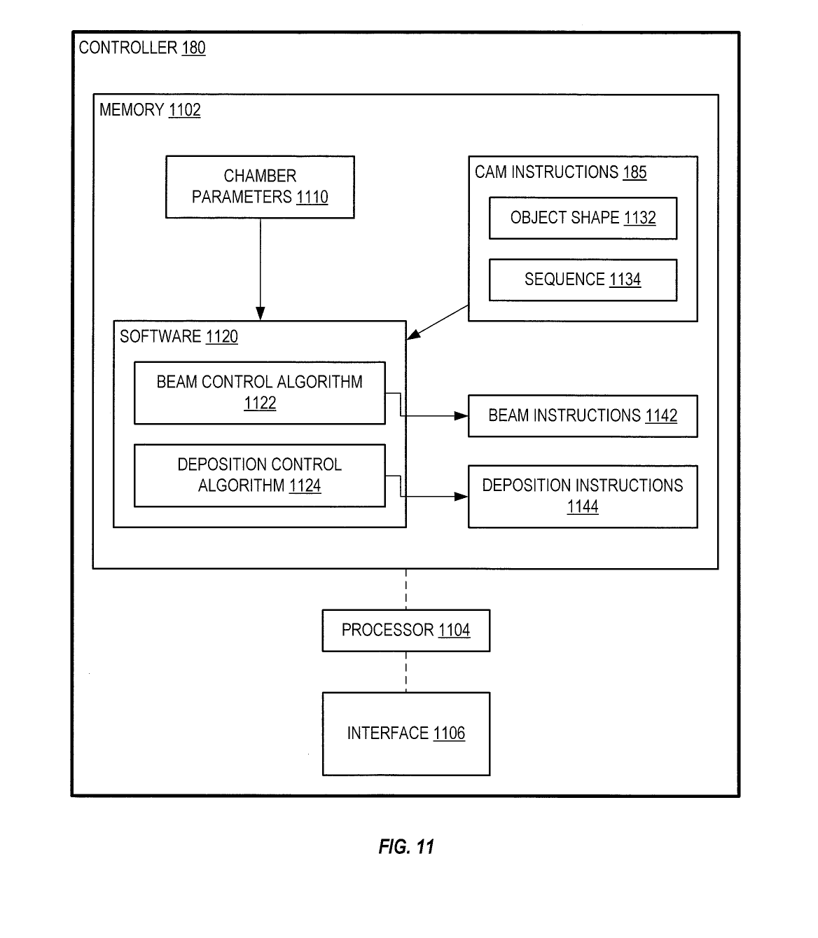

Controller 180 is shown in exemplary detail in FIG. 2 and FIG. 11. One or more instruments are configured to determine parameters of deposition chamber 150 and provide chamber parameter information to controller 180 in real-time. Chamber parameters define: (a) chamber conditions, such as temperature, pressure, atmosphere, and microwave power distribution in chamber 150, and (b) parameters related to workpiece 160. Measuring chamber parameters enables real-time feedback to controller 180 for active and adaptive control of material deposition (e.g., deposition rate) and microwave beam properties (e.g., beam size, power density, frequency). Methods for determining chamber conditions include several known instruments. To monitor temperature, uniformity, heat distribution and dissipation and other parameters of workpiece 160, an infrared camera is for example provided with a radio frequency (RF) filter to protect the camera lens from small amounts of microwave energy which could escape the nozzle. An RF diode or a harmonic mixer is configured to provide real-time frequency measurements for feedback control of microwave source 120. In an embodiment, one or more fluid loops are configured such that changes in temperature of the fluid are used as an indication of microwave power level. In an embodiment, more precise bolometric measurement tools are used to measure precise power output of the high power microwave source 120. Instrumentation provides feedback on the application of microwave energy to workpiece 160, including for example an optical pyrometer or another sensor disposed so as to observe temperatures at one or more locations on workpiece 160. Knowledge and control of a wide range of environmental and process parameters are an integral part of fabricating complex objects. Controller 180 is configured to control parameters based on their real-time measurements, thus leading to an adaptive rather than fully predetermined manufacturing process. In an embodiment, controller 180 conducts simulations and analysis based on measured chamber parameters and uses the results to adapt CAM set of instructions 185 during the manufacturing process.

FIG. 2 shows a cross-sectional view of a fused material deposition microwave system 200, which is an example of system 100 of FIG. 1. A dashed line 101 is drawn on the side and top of system 100 of FIG. 1 to illustrate the location of cross-section used for FIG. 2. System 200 includes four material sources 230(1), 230(2), 230(3), and 230(4) for supplying four materials 235(1), 235(2), 235(3), and 235(4). The amount of material 235(1) flowing to deposition nozzle 110 is for example controlled by an electro-mechanical shutter 236(1). Only material 235(1) and electro-mechanical shutter 236(1) are noted in FIG. 2 for clarity. Examples of material 235 include metals, ceramics, pre-ceramic polymers, and plastics.

It should be appreciated that mechanisms controlling flow of materials from material sources 230 can be different from electro-mechanical shutter 236(1) and are determined by properties of the material. For example, when material is in the form of suspension, a valve may be used to control the flow. Other mechanisms known in the art may be used to supply material without limiting the scope of the invention.

Metals are naturally reflective making them difficult to heat with microwave energy, but metallic powders may be configured to be highly absorptive. Absorptivity and thermal characteristics of metallic and ceramic powders are configured for example by adjusting size and form of particles, adding small quantities of various secondary materials, creating mixtures, and by a number of other means known in the art and actively researched today. To increase microwave interaction and to enable easier delivery of materials 235 from hoppers 230 to nozzle 110 via conduit 140, materials 235 are in the form of a powder, nano-particle, gel, suspension or other form. In an embodiment, powdered materials 235 are carried to nozzle 110 via an added medium such as a flow of gas or fluid that picks up materials 235 leaving hoppers 230 and carrying them to nozzle 110. A pump (not shown) may be used to establish positive pressure between hoppers 230 and nozzle 110 to assist material 235 deposition. A conduit 240 guides materials 235 as illustrated by an arrow 238. Conduit 240 is configured for example with channels to independently guide a plurality of materials to deposition nozzle 110 (see FIG. 8).

Materials 235 are added layer by layer, with a plurality of layers being added. In an embodiment, layers of differing materials are added such that they bond to one another (e.g., metal disposed adjacent to ceramic or a metal deposited on a layer of metal) providing three-dimensional objects made of metals, ceramics and other materials in commercially significant quantities with consistent high quality. Accordingly, production efficiency and quality are improved, while costs and other requirements such as manufacturing time are reduced relative to conventional additive manufacturing systems and methods involving metallic and ceramic materials.

Returning to FIG. 2, conduit 240 includes a waveguide 245 that guides a beam of microwave energy 225 from microwave energy source 120 to deposition nozzle 110. In an embodiment, microwave beam 225 is a Gaussian beam. In an embodiment, microwave beam 225 is a high-power millimeter-wave beam. The use of millimeter frequencies, such as for example 20-180 GHz, allows for precise and adjustable control of the beam and its energy distribution. Millimeter waves of approximately 20-180 GHz can be controlled and propagated from microwave source 120 to nozzle 110 via waveguide 245 of mm- and cm-size dimensions thus conforming to dimensions adequate for additive manufacturing applications as distinguished from low frequency radiation such as 2.45 GHz. Millimeter waves generated with high power microwave sources such as gyrotrons are typically generated with high efficiencies (40-60%) at high power levels (above 20 kW) and are significantly more powerful and more efficient than lasers used in additive manufacturing applications. Furthermore, compared to laser beams, microwave beam 225 is more spread-out and penetrates deeper into material 235, providing more uniform energy distribution. Advantages include faster deposition, decreased cost, and increased speed of production for large structures.

In some cases, it is beneficial to control the frequency of microwave beam 225. The frequency of microwave beam 225 is directly related to the strength of magnetic field, which causes gyration of electrons in the electron beam current flowing inside the gyrotron cavity. Although in many cases vacuum tubes, like gyrotrons, are designed to operate at a specific frequency determined by both the magnetic field and tube design, it is possible to vary the frequency in a number of ways, by for example using a step tunable gyrotron. By decreasing the field with a fixed multiple it is possible to operate the gyrotron at a different frequency while outputting a different mode. Also, by small changes in the magnetic field, it is possible to change the output frequency by a small amount (e.g., from 90 GHz to 90.5 GHz), which may be beneficial in some special use cases. The frequency is also affected by the geometry of the gyrotron's cavity, such that microwaves are emitted most efficiently at certain multiples of the magnetic field. The control over frequency is beneficial in manufacturing various materials, where said materials are optimized and configured to preferentially absorb microwaves of a specific frequency.

Again returning to FIG. 2, an arrow 228 illustrates the direction of travel of microwave beam 225. In an embodiment, waveguide 245 is a flexible corrugated tube adapted to guide microwave beam 225. In some embodiments waveguide 245 comprises walls configured to absorb a portion of microwave energy, thereby pre-heating material 235 flowing through conduit 240. Side-to-side movement of deposition nozzle 110 along first rail 112 is illustrated by arrows 215. Up/down movement of deposition nozzle 110 and first rail 112 along second rail 114 is illustrated by arrows 217. In an embodiment, front/back movement of deposition nozzle 110 and first rail 112 occurs along a third rail (not shown), thus enabling deposition nozzle 110 to move in three dimensions. In an embodiment, movement of deposition nozzle 110 includes manipulating a position or orientation with one or more servo motors responsive to commands from controller 180. In an alternate embodiment, controller 180 receives signal(s) that indicate where materials 235 are deposited, thereby instructing deposition in a desirable manner (e.g., to create a desired object shape). System 200 may include more than one deposition nozzle 110, thereby enabling simultaneous deposition of more than one material 235 in separate locations of workpiece 160.

System 200 allows fabrication of very high quality parts made of various steels, refractory metals, and ceramics. The ability to manipulate the position and orientation of deposition nozzle 110, coupled with moveable base 170, enables several advantageous uses. For example, to repair a defect such as a crack within workpiece 160, fused material deposition system 200 applies molten material directly to the crack and over the crack thereby fixing the structural damage.

In an embodiment, system 200 applies microwave energy to internal portions of workpiece 160 without at the same time adding material 235. This allows pre-heating workpiece 160 before starting deposition of a new material layer, which is beneficial in certain applications.

In another embodiment, system 200 is configured to adjust deposition nozzle 110 and flow of the material 235 to allow a controlled portion of energy from microwave beam 225 to escape from nozzle 110. This energy would heat an area adjacent to the location of material deposition bringing the temperature of workpiece 160 closer to the temperature of the newly deposited layer of material. Pre-heating all or part of workpiece 160 with microwave beam 225 may be beneficial for reducing thermal stress and alleviating thermal relaxation during the cooling process.

In some cases it is beneficial to maintain microwave beam 225 on workpiece 160 after a layer of material is deposited and flow of material 235 has ceased. This allows a more gradual and uniform cooling of workpiece 160. To achieve a desirable cooling rate, deposition nozzle 110 is for example configured to output microwave beam 225 with a predetermined shape and intensity for providing uniform distributed microwave heating to workpiece 160 during the cooling process. Shape of beam 225, amount of power from microwave energy source 120, and rate and duration of material 235 deposition are controlled by controller 180 through CAM set of instructions 185, based on chamber parameters and properties of workpiece 160.

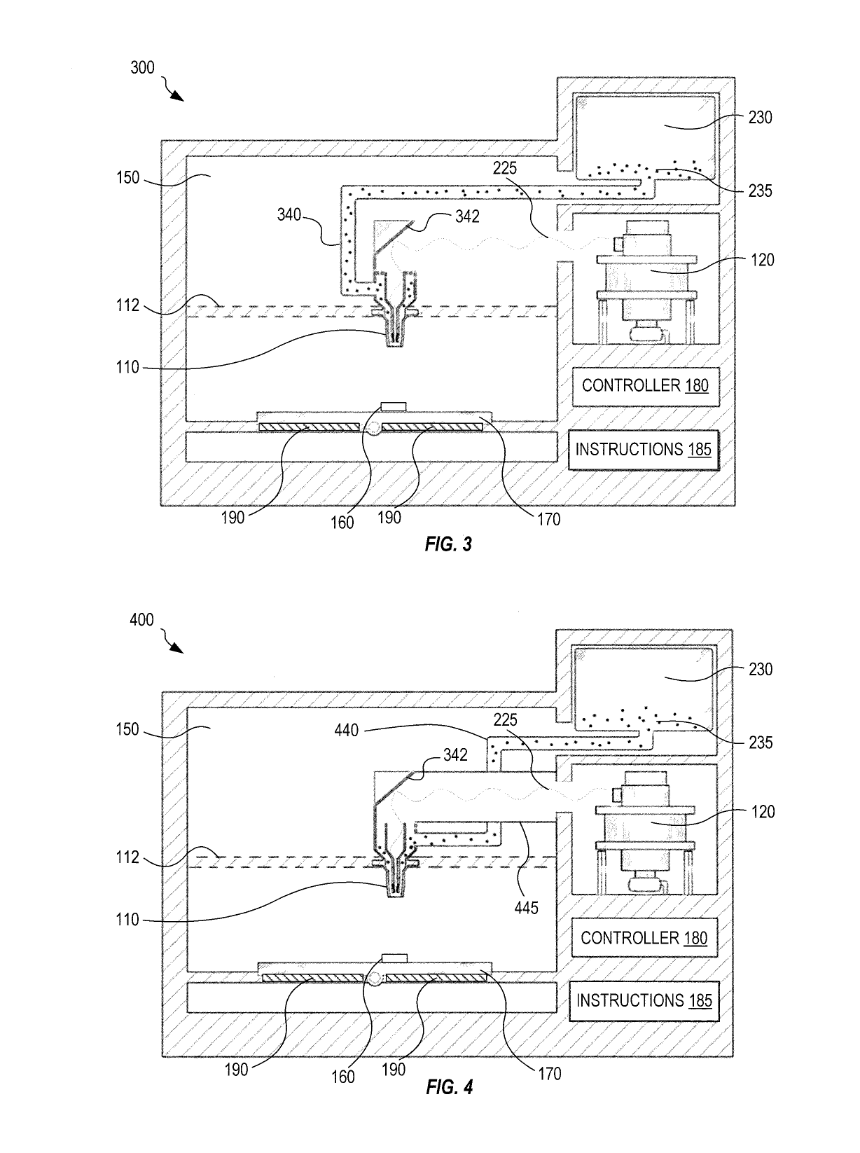

FIG. 3 shows a cross-sectional view of a fused material deposition microwave system 300. System 300 is a different implementation of system 100 of FIG. 1. Location of the cross-section through system 300 is similar to dashed line 101 of FIG. 1. System 300 includes conduit 340 configured to guide material 235 to deposition nozzle 110, and a reflector 342 configured to reflect microwave beam 225 to deposition nozzle 110. Although only one reflector 342 is shown in FIG. 3, system 300 may include any number of reflectors for focusing and directing microwave beam 225 to deposition nozzle 110. Reflectors are well suited for creating large objects, while flexible waveguides, such as in FIG. 2, allow a higher degree of control.

FIG. 4 shows a cross-sectional view of a fused material deposition microwave system 400. System 400 is a different implementation of system 100 of FIG. 1. Location of the cross-section through system 400 is similar to dashed line 101 of FIG. 1. System 400 includes conduit 440 configured to guide material 235 to deposition nozzle 110. System 400 includes a waveguide 445, which has at least one reflector 342 configured to reflect microwave beam 225 to deposition nozzle 110. In this embodiment, waveguide 445 is configured primarily to prevent microwaves escaping into the chamber rather than for guiding beam 225, while most of the guiding function is performed by reflector 342. Waveguide 445 optionally houses microwave diagnostics such as bolometers and frequency measuring sensors to provide real-time feedback to controller 180 for controlling output of microwave source 120. In an embodiment, waveguide 445 includes zero, one, or more, each of mirrors, horns, phase manipulators, launchers, and beam isolators to further manipulate microwave beam 225 without departing from the scope hereof. In an embodiment, beam isolators are located at microwave source 120 output, in waveguide 445, or in deposition nozzle 110 to control power of microwave beam 225.

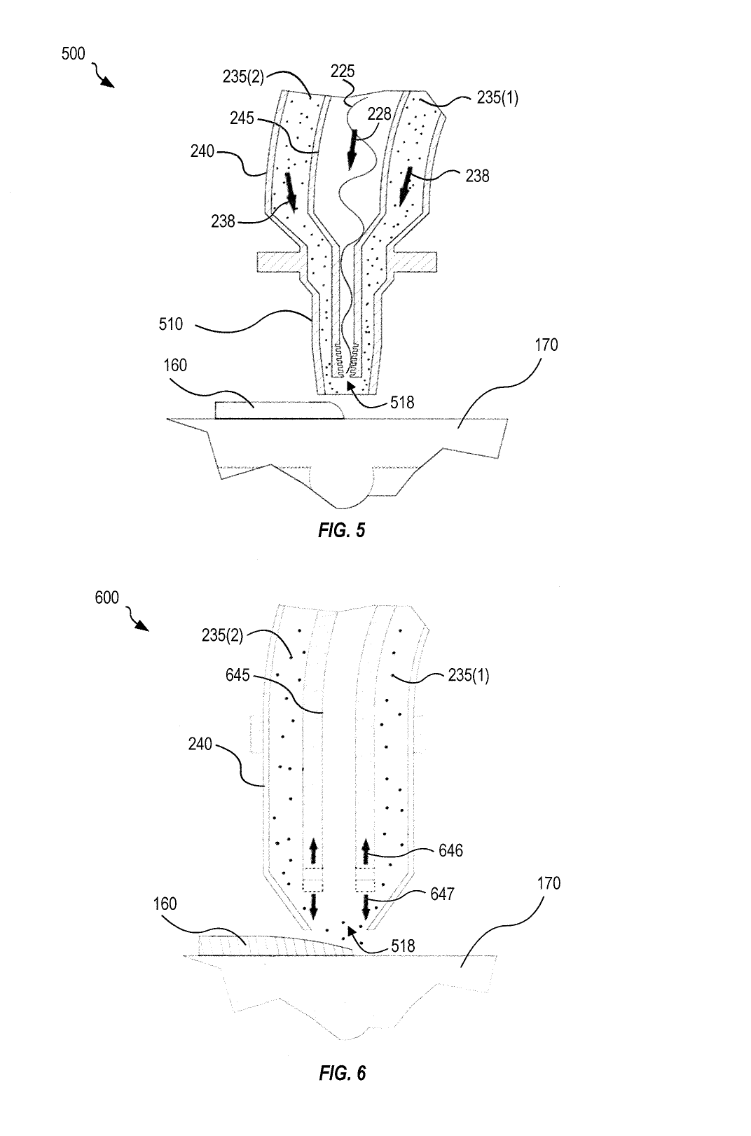

FIG. 5 shows a cross-sectional view of a portion of a fused material deposition microwave system 500. System 500 includes deposition nozzle 510, which is an embodiment of deposition nozzle 110 of FIG. 1. FIG. 5 further illustrates a nozzle outlet 518 of deposition nozzle 510. System 500 is configured to deliver materials 235(1), 235(2) through channels of conduit 240 in direction 238 to nozzle outlet 518. System 500 uses controller 180 to control delivery rates of one or more materials according to CAM set of instructions 185. Thus, materials 235(1), 235(2) may be delivered from material sources 230(1), 230(2) simultaneously or sequentially and at similar or differing rates, thereby enabling formation of complex workpieces.

System 500 includes waveguide 245 to guide microwave energy beam 225 in direction 228 to nozzle outlet 518. Inside nozzle outlet 518, microwave energy beam 225 interacts with one or more materials 235. The amount of energy needed to melt material 235 is computed by controller 180 based on the material used (defined in the CAM set of instructions 185). The amount of energy is controlled by adjusting the output of microwave energy source 120 or by introducing attenuation into the path of microwave beam 225. Attenuation can be accomplished by changing the reflecting properties of waveguide 245 or one or more reflectors, such as reflector 342 of FIGS. 3 and 4. Attenuation is also accomplished for example by means of a controllable isolator introduced into waveguide 245 or at the output of microwave source 120.

In some embodiments, a fraction of microwave energy is reflected back to microwave source 120 from mirrors, nozzles, or other parts of the system. In such cases, it is beneficial to introduce an isolator at the output of microwave source 120.

In an embodiment, waveguide 245 is highly reflective, leading to low loss of microwave energy. In an alternative embodiment, waveguide 245 absorbs a fraction of microwave energy, thereby pre-heating material 235 as it flows through conduit 240. Pre-heating material 235 causes faster melting in nozzle outlet 518, thereby enabling faster deposition rates.

In an embodiment, nozzle outlet 518 has a mechanically adjustable diameter that is controlled by controller 180 according to CAM set of instructions 185. Increasing the diameter of nozzle outlet 518 enables faster deposition rates. Conversely, decreasing the diameter of nozzle outlet 518 reduces droplet size of molten material thereby improving resolution for depositing material. The diameter of nozzle outlet 518 is matched to a material melting rate, which depends on parameters of microwave beam 225, delivery rates of one or more materials 235 from material source 230, properties (e.g., conductivity and permittivity) of one or more materials 235, and the fraction of microwave energy absorbed by waveguide 245.

FIG. 6 shows a cross-sectional view of a deposition nozzle 600, which is an embodiment of deposition nozzle 110 of FIG. 1. Deposition nozzle 600 includes an adjustable waveguide 645, which is configured to move positions relative to conduit 240. Arrows 646 and 647 show up and down motion of waveguide 645, respectively. Adjusting the position of waveguide 645 relative to conduit 240 increases or decreases the volume of material 235(1), 235(2) to be melted through interaction with microwave energy beam 225 in nozzle outlet 518. Position of waveguide 645 relative to conduit 240 is controlled by controller 180 according to CAM set of instructions 185. An adjustable position of waveguide 645 relative to conduit 240 provides an additional controllable feature for controlling melting of different materials.

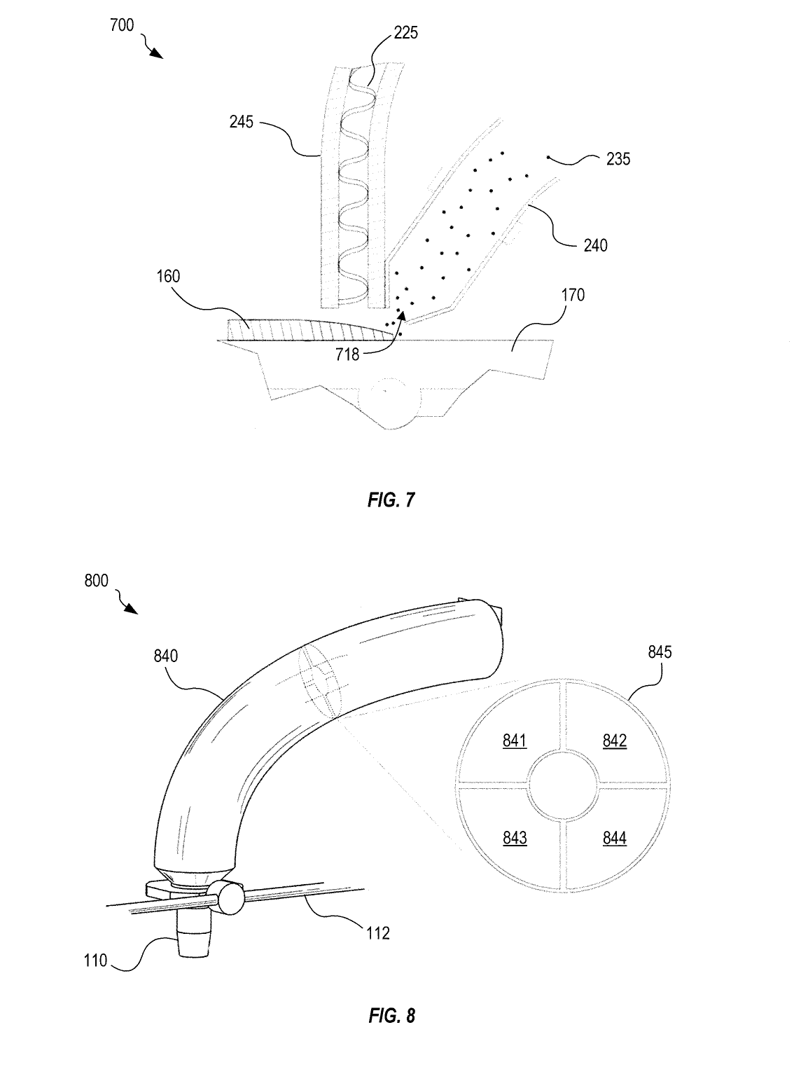

FIG. 7 shows a cross-sectional view of a deposition nozzle 700, which incorporates the same principles as the deposition nozzle 110 of FIG. 1, but allows a different arrangement of components within the fused material deposition system. Deposition nozzle 700 includes waveguide 245 disposed outside of conduit 240. Microwave energy beam 225 heats material 235 outside a nozzle outlet 718 as material 235 is deposited. In an embodiment, material 235 is sprayed from nozzle outlet 718 near the end of waveguide 245, thereby adding material 235 to workpiece 160. In an embodiment, material source 230 includes a pump to supply increased pressure for spraying material 235. Control of the pump is performed by controller 180 according to CAM set of instructions 185.

FIG. 8 shows a portion of a fused material deposition microwave system 800. System 800 includes a conduit 840, which is an embodiment of conduit 140 of FIG. 1. Conduit 840 includes channels 841, 842, 843, and 844, shown in a cross-sectional view 845 that are configured to transport different materials to deposition nozzle 110. Conduit 840 includes four channels but may include fewer or greater than four depending on the number of different materials desired.

In a preferred embodiment, the fused material deposition microwave system 800 includes a deposition nozzle 110 that is adjustable and controllable in position, orientation, and outlet diameter; in this way such a configurable deposition nozzle 110 is particularly suited for deposition of powdered materials heated beyond melting point. Control over nozzle 110 allows for fabrication of parts with varying materials while improving deposition speed and localization of powder deposition onto workpiece 160. Waveguide 245 is accordingly matched to a specific form of high power millimeter-wave microwave energy 225, which further allows for robust control over beam characteristics.

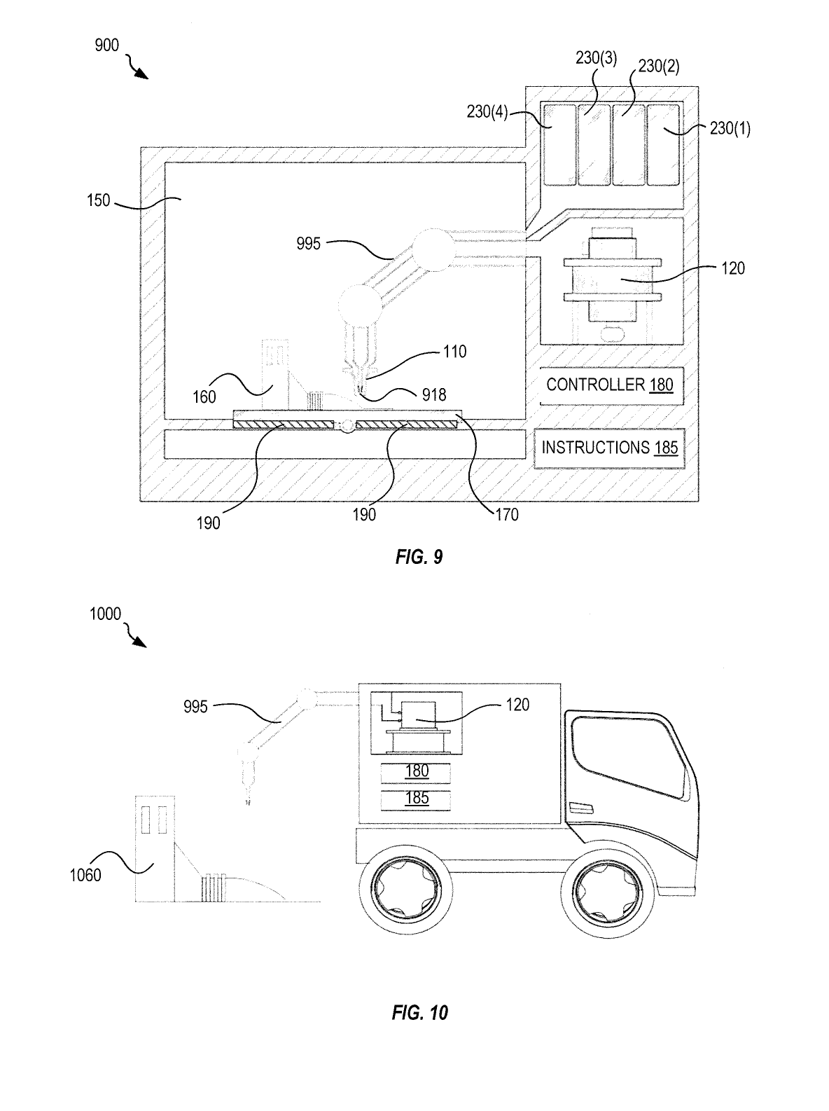

FIG. 9 shows a cross-sectional view of a fused material deposition microwave system 900. System 900 is an alternative implementation of a system 100 of FIG. 1. Location of the cross-section through system 900 is similar to dashed line 101 of FIG. 1. System 900 includes a robotic arm 995 for moving position and orientation of deposition nozzle 110 in three dimensions, thereby positioning a nozzle outlet 918 with controller 180 according to CAM set of instructions 185. In this embodiment, the positioning of deposition nozzle 110 is accomplished with robotic arm 995 for greater flexibility compared to using rails.

FIG. 10 shows a cross-sectional view of a mobile fused material deposition microwave system 1000. System 1000 is an example of system 100 of FIG. 1. System 1000 is configured on a vehicle to provide a mobile fused material deposition microwave system. Mobile system 1000 is adapted to perform fused material deposition outside of a chamber with controlled atmosphere by equipping robotic arm 995 with a gas hose that is integrated with, or attached to, deposition nozzle 110. Robotic arm 995 is for example configured to supply a flow of oxygen-free gas, such as hydrogen, nitrogen or argon, to prevent oxidation. Disposing non-oxidative gas while depositing molten material prevents oxidation and cools the molten material. Advantages of mobile system 1000 include the ability to fabricate complex components in remote locations and the ability to repair or modify existing infrastructure such as bridges. Thus, workpiece 1060 represents either a newly built workpiece or an existing object to be repaired or modified.

FIG. 11 shows controller 180 in further exemplary detail. Controller 180 is for example a computer that includes a memory 1102, a processor 1104, and an interface 1106 for receiving CAM set of instructions 185. Memory 1102 stores software 1120 that includes machine readable instructions that when executed by processor 1104 provide control and functionality of system 100 as described herein. Software 1120 includes a beam control algorithm 1122 and a deposition control algorithm 1124.

Beam control algorithm 1122 provides instructions to control microwave beam 225 properties (e.g., beam size, power density). Beam control algorithm 1122 operates to process chamber parameters 1110 and CAM set of instructions 185 to generate beam instructions 1142 that control operation of microwave energy source 120 for each step in generating workpiece 160. Chamber parameters 1110 provide for example the size, shape, and contents of deposition chamber 150 to software 1120. Chamber parameters 1110 also provide for example parameters within the chamber such as temperature, pressure, and atmosphere to software 1120. In some embodiments, chamber parameters 1110 are real-time parameters that provide a variety of changing characteristics at every step of the deposition process, including for example thermal infrared images of workpiece 160 provided after, and in between, each step of the process.

Beam control algorithm 1122 may use a simulation model employing basic physics principles to compute necessary beam instructions 1142 after every step based on chamber parameters 1110. The simulation model is for example custom written, but its principle of operation, which is based on thermo-mechanical, fluid dynamic and electromagnetic principles, may be similar to COMSOL, ANSYS, Autodesk Simulation 360, or any other physics based simulation tool. Note that the simulation runs within controller 180, or optionally controller 180 uses an external computer, such as a remote or a cloud-based server, wherein controller 180 uses an Internet connection to exchange data with the remote computer.

CAM set of instructions 185 includes an object shape 1132, which defines the shape of the workpiece 160 being generated, a sequence 1134 that defines steps for generating each layer of workpiece 160, and instructions for control of microwave beam 225 during each step of the process. For example, CAM set of instructions 185 defines the three-dimensional shape of the object to be generated and the type of material for each layer added to workpiece 160. A sequence 1134 that defines steps for generating each layer is for example an adjustable sequence that is modified based on the input of chamber parameters 1110 during each step of the deposition process by software 1120. Beam instructions 1142 for control of microwave beam 225 are for example an adjustable set of instructions modified by software 1120 during each step of the deposition process based on chamber parameters 1110.

Deposition control algorithm 1124 processes CAM set of instructions 185 and chamber parameters 1110 to generate deposition instructions 1144 that control deposition nozzle 110 to deposit material 235 on workpiece 160, control flow of material 235 to the nozzle 110, control timing and rate of deposition, control cooler 190, and in some embodiments provide other control functions as needed.

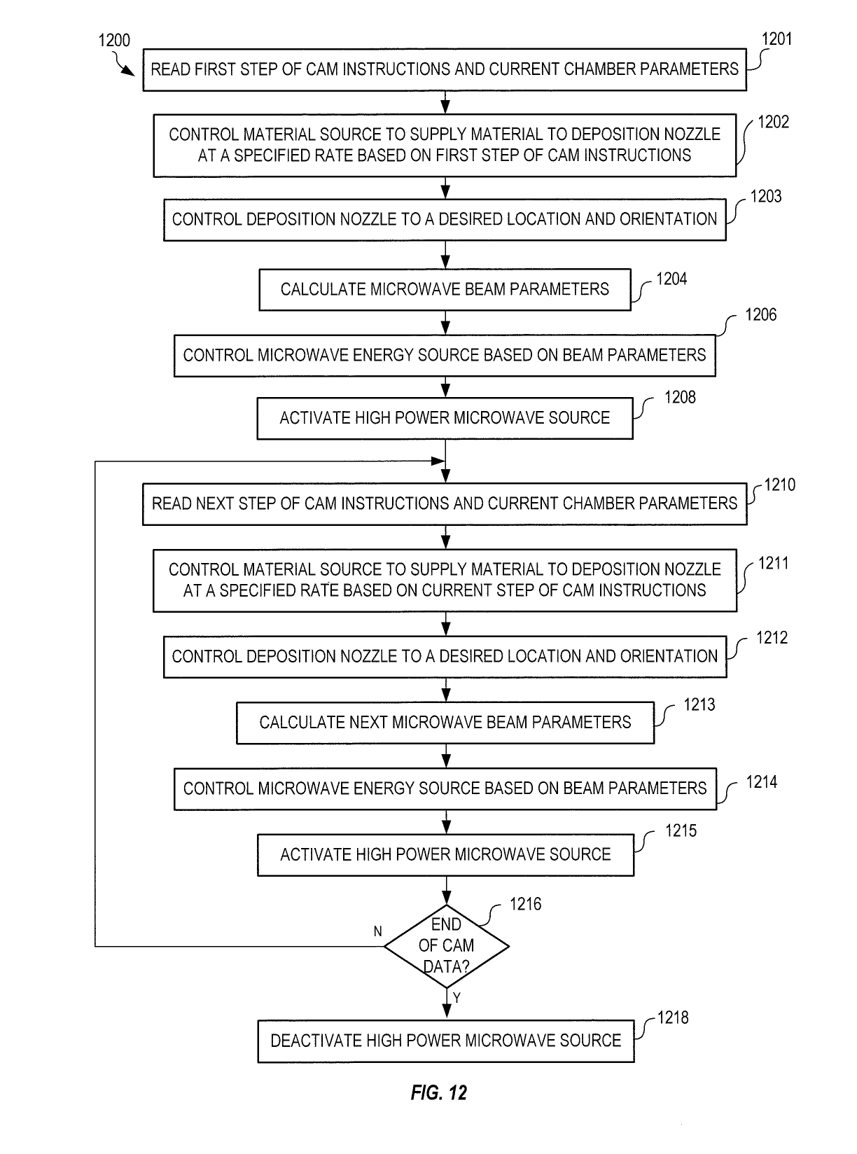

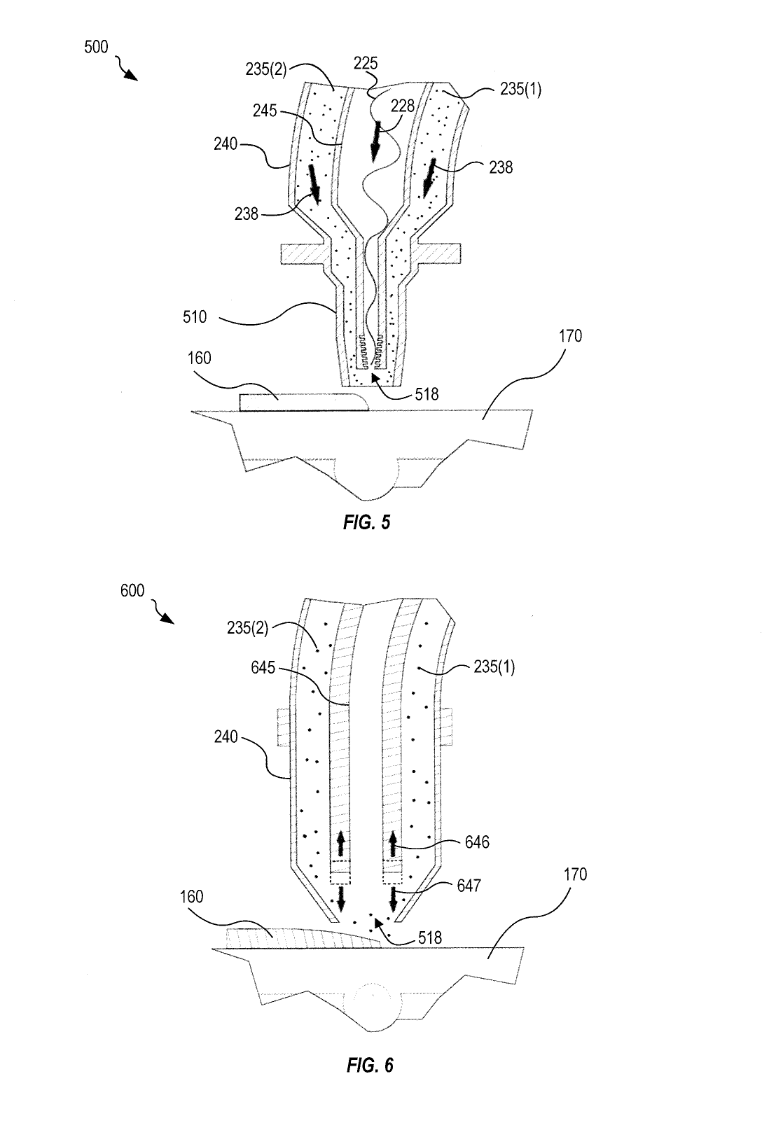

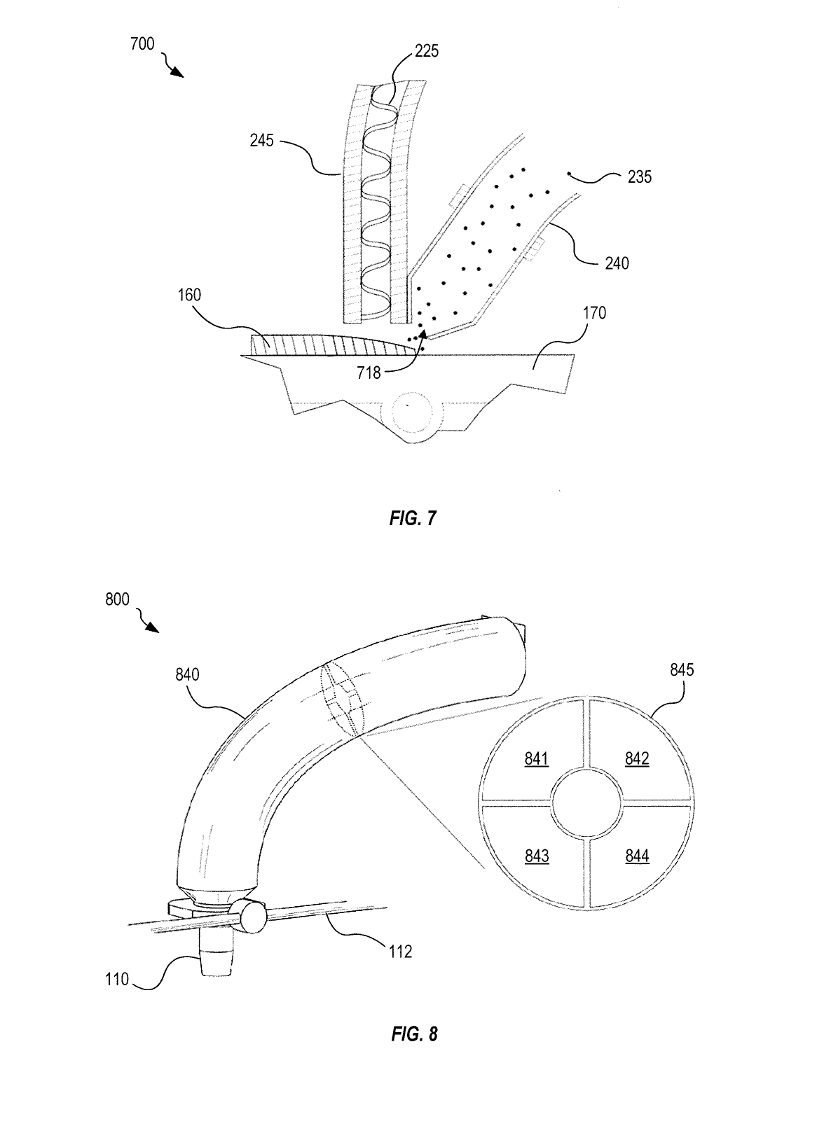

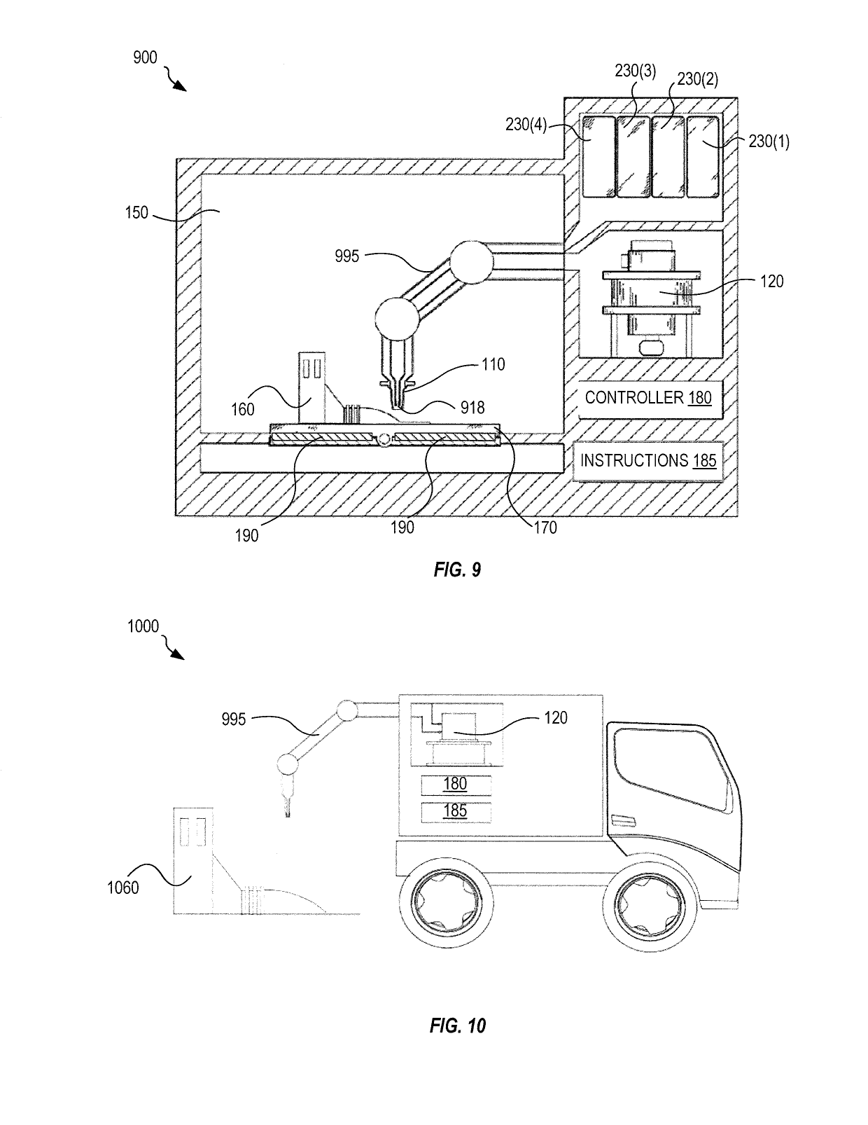

FIG. 12 is a flowchart illustrating one exemplary fused material deposition microwave method 1200. Method 1200 is for example implemented within software 1120 of controller 180.

In step 1201, method 1200 reads a first step from CAM set of instructions 185 and current chamber parameters 1110. In one example of step 1201, software 1120 reads information of a first step for creation of a workpiece 160 from sequence 1134 of CAM set of instructions 185.

In step 1202, method 1200 controls material source 230 to supply material 235 at a specified rate through conduit 240 to deposition nozzle 110. In one example of step 1202, software 1120 controls material source 230 to supply material 235 at a specified rate through conduit 240 to deposition nozzle 110 based upon the first step of CAM set of instructions 185.

In step 1203, method 1200 positions nozzle 110 to a desired location and orientation. In one example of step 1203, software 1120 controls deposition nozzle 110 to a desired location and orientation based on the first step of CAM set of instructions 185.

In step 1204, method 1200 calculates microwave beam 225 parameters. In one example of step 1204, software 1120 invokes beam control algorithm 1122 to calculate beam instructions 1142 based upon chamber parameters 1110, object shape 1132, and first step of sequence 1134. In an embodiment, beam instructions 1142 include one or more of (i) power of the beam, (ii) time of the pulse, and (iii) frequency of the beam (if for example microwave energy source 120 is multi-frequency).

In step 1206, method 1200 controls microwave energy source based upon microwave beam 225 parameters. In one example of step 1206, software 1120 sends beam instructions 1142 from controller 180 to microwave energy source 120. In an embodiment, software 1120 sends beam control instructions to mirrors and isolator(s) within the waveguide when such additional control is needed.

In step 1208, method 1200 activates high power microwave energy source 120. In one example of step 1208, software 1120 sends beam parameters defined within beam instructions 1142 to microwave energy source 120, wherein microwave energy source 120 generates microwave beam 225 based upon the beam parameters.

It must be appreciated that the time between steps 1201, 1202, 1203, 1204, 1206 and 1208 can be extremely small so as to be considered negligible for a mechanical system, where motion of various components such as nozzle actuators, pump actuators and other mechanical components operate much slower than deposition instructions 1144.

In step 1210, method 1200 reads a next step of the CAM set of instructions 185 and current chamber parameters 1110. In one example of step 1210, software 1120 reads a next step for manufacturing workpiece 160 from sequence 1134 of CAM set of instructions 185. Based on CAM set of instructions 185 and chamber parameters 1110, beam control algorithm 1122 and deposition control algorithm 1124 may be adjusted.

In step 1211, method 1200 controls material source 230 to supply material 235 at a specified rate through conduit 240 to deposition nozzle 110. In one example of step 1211, software 1120 controls, material source 230 to supply material 235 at a specified rate through conduit 240 to deposition nozzle 110 based upon the current step of CAM instructions 185.

In step 1212, method 1200 positions nozzle 110 to a desired location and orientation. In one example of step 1212, software 1120 controls deposition nozzle 110 to a desired location and orientation based on the current step of CAM set of instructions 185.

In step 1213, method 1200 calculates next microwave beam 225 parameters. In one example of step 1213, software 1120 invokes beam control algorithm 1122 to calculate beam instructions 1142 based upon current chamber parameters 1110, object shape 1132, and the current step of sequence 1134.

In step 1214, method 1200 controls microwave energy source 120 based upon microwave beam 225 parameters. In one example of step 1214, software 1120 sends beam instructions 1142 from controller 180 to microwave energy source 120. In an embodiment, software 1120 sends beam instructions 1142 to mirrors and isolator(s) within the waveguide when such additional control is needed.

In step 1215, method 1200 activates high power microwave energy source 120. In one example of step 1215, software 1120 sends beam parameters defined within beam instructions 1142 to microwave energy source 120, wherein microwave energy source 120 generates microwave beam 225 based upon the beam parameters.

Step 1216 is a decision. If, in step 1216, method 1200 determines that the end of the CAM set of instructions 185 has been reached, method 1200 continues with step 1218; otherwise, method 1200 repeats steps 1210 through 1216.

In step 1218, method 1200 deactivates the high power microwave energy source. In one example of step 1218, software 1120 sends a control signal to deactivate microwave energy source 120. Method 1200 then terminates.

This disclosure has been described above primarily with reference to its application in a 3D additive manufacturing system. It should be clear to one skilled in the art of material processing and additive manufacturing, however, that systems of other varied configurations and for other uses such as part repairs and material processing can be envisaged without being limited to those examples provided herein.

Changes may be made in the above methods and systems without departing from the scope hereof. It should thus be noted that the matter contained in the above description or shown in the accompanying drawings should be interpreted as illustrative and not in a limiting sense. The following claims are intended to cover all generic and specific features described herein, as well as all statements of the scope of the present method and system, which, as a matter of language, might be said to fall therebetween.

What is claimed is:

1. Fused material deposition microwave system, comprising:
a high power microwave source;
at least one deposition nozzle having adjustable outlet diameter for depositing one or more materials;
a waveguide for guiding microwave energy to the deposition nozzle to melt the materials;
a material source to supply one or more materials to the deposition nozzle; and
a controller for controlling the deposition nozzle, microwave energy flow, and material source according to a computer-aided manufacturing (CAM) set of instructions to deposit and fuse molten material on a workpiece.

2. The system of claim 1, in which the high power microwave source is a step tunable gyrotron capable of outputting microwaves at more than one frequency.

3. The system of claim 1, the at least one deposition nozzle comprising a nozzle configurable to guide microwaves of a specified frequency range determined by a microwave source, according to the CAM set of instructions.

4. The system of claim 1, the at least one deposition nozzle comprising a nozzle configurable for adjusting position and orientation for guiding microwaves and material relative to the workpiece, according to the CAM set of instructions.

5. The system of claim 1, the deposition nozzle being configurable to output a controlled portion of microwave energy before, after or during material deposition to heat the workpiece, partially or completely, in areas adjacent to location of material deposition.

6. The system of claim 1, further comprising a robotic arm for moving the deposition nozzle in three dimensions, thereby positioning a nozzle outlet according to the CAM set of instructions.

7. The system of claim 1, the deposition nozzle connected to the material source and further comprising a pump for increasing pressure inside the material source to assist deposition of material.

8. The system of claim 1, the waveguide comprising one or more of reflectors and beam shaping mirrors adapted to guide microwave energy.

9. The system of claim 1, the waveguide comprising a flexible corrugated tube adapted to guide microwave energy.

10. The system of claim 1, the waveguide enclosed in a conduit carrying one or more materials.

11. The system of claim 10, the waveguide comprising walls configured to absorb a portion of microwave energy, thereby pre-heating the material flowing through the conduit.

12. The system of claim 10, comprising an adjustable position of the waveguide relative to the nozzle outlet, thereby adjusting material melting volume.

13. The system of claim 1, the material source comprising a plurality of channels for delivering materials to the deposition nozzle, thereby enabling deposition of multiple materials separately or as a mixture.

14. The system of claim 1, further comprising a moveable base for moving the workpiece during material deposition according to the CAM set of instructions.

15. The system of claim 1, further comprising a deposition chamber for containing the workpiece.

16. The system of claim 15, the deposition chamber being filled with controlled atmosphere.

17. The system of claim 15, the deposition chamber comprising at least one instrument that measures parameters related to the workpiece and chamber atmosphere during material deposition.

18. The system of claim 15, the deposition chamber being partially filled with liquid configured to conduct away heat produced during material deposition.

19. The system of claim 15, the deposition chamber comprising a cooler that removes heat from the molten material.

20. The system of claim 19, the cooler being controlled by the controller according to the CAM set of instructions and the measured parameters.

21. The system of claim 1, the deposition nozzle being configurable to output microwave beams of predetermined shape and intensity to provide uniform distributed microwave heating to the workpiece during cooling.

22. The system of claim 1, wherein the nozzle is configured to supply flow of a non-oxidative gas or liquid to the workpiece thereby preventing oxidation.

23. The system of claim 22 comprising a vehicle wherein material deposition occurs outside of a chamber and non-oxidative gas is deposited to prevent oxidation and cool molten material.

24. Fused material deposition microwave method, comprising:
delivering one or more materials to a deposition nozzle;
guiding microwave energy from a high power microwave source to the deposition nozzle to melt the one or more materials; and
controlling the material delivery, microwave energy, and position of the deposition nozzle according to a computer-aided manufacturing (CAM) set of instructions, thereby depositing and fusing molten material into a workpiece.

25. The method of claim 24, the step of guiding microwave energy comprising heating the material with the microwave energy inside the deposition nozzle prior to depositing the molten material.

26. The method of claim 24, further comprising preheating material as it moves through a conduit surrounding a microwave waveguide, wherein waveguide walls are configured to absorb a portion of microwave energy.

27. The method of claim 24, the step of guiding microwave energy comprising heating material with the microwave energy outside the deposition nozzle as the material is deposited.

28. The method of claim 24, further comprising (a) measuring one or more parameters related to one or both of the workpiece and a deposition chamber containing the workpiece, and (b) controlling the controller according to the CAM set of instructions and the one or more measured parameters.

29. The method of claim 24, in which the properties of the microwave beam are measured with bolometers incorporated into the waveguide, mirrors and nozzle.

30. The method of claim 24, further comprising modifying initial CAM instructions during material deposition based on simulations and analysis conducted using measured chamber parameters.

31. The method of claim 24, further comprising removing heat from the workpiece.

32. The method of claim 31, further comprising removing heat with a gas or liquid directed to the workpiece.

33. The method of claim 32, further comprising distributing the gas or liquid from a conduit attached to or incorporated into the nozzle.

34. The method of claim 31, further comprising circulating water or other cooling liquid to the printing base plate.

35. The method of claim 31, further comprising immersing the nozzle into a liquid within the deposition chamber.

36. The method of claim 31, further comprising providing microwave beam energy to the workpiece during cooling to alleviate thermal stresses at final product.

37. The method of claim 31, further comprising controlling the nozzle to output controlled amount of microwave energy onto the workpiece before, after and during deposition of material.

38. The method of claim 37, the amount of microwave energy providing sufficient heating of deposition area to eliminate thermal stresses at final product.

39. The method of claim 24, further comprising removing air from nearby the workpiece.

40. The method of claim 39 in which air in the deposition chamber is displaced with a non-oxidative gas, thereby creating a substantially oxygen-free atmosphere in the chamber.

41. The method of claim 40, in which air is displaced by a flow of non-oxidative gas or hydrogen gas directed from a hose configured with the deposition nozzle.
